(19) United States
(12) Patent Application Publication
(10) Pub. No.: US 2014/0262769 A1
(43) Pub. Date: Sep. 18, 2014

(54) SUBSTRATE HOLDER APPARATUS AND VACUUM PROCESSING APPARATUS

(71) Applicant: CANON ANELVA CORPORATION, Kawasaki-shi (JP)

(72) Inventors: Yasushi MIURA, Kawasaki-shi (JP); Eiji FUJIYAMA, Chigasaki-shi (JP); Masaaki ISHIDA, Kawasaki-shi (JP)

(73) Assignee: CANON ANELVA CORPORATION, Kawasaki-shi (JP)

(21) Appl. No.: 14/293,471

(22) Filed: Jun. 2, 2014

Related U.S. Application Data
(63) Continuation of application No. PCT/JP2012/005406, filed on Aug. 28, 2012.

(30) Foreign Application Priority Data
Dec. 15, 2011 (JP) 2011-275074

(51) Int. Cl. H01J 37/32

(52) U.S. Cl. CPC H01J 37/32715; H01J 37/32733
USPC 204/298.15

(57) ABSTRACT

A substrate holder apparatus includes a substrate holder configured to hold a substrate in a vacuum processing space in a chamber, a support column coupled to the substrate holder, a first rotating support unit which rotatably supports the support column, a second rotating support unit which rotatably supports the support column at a position spaced apart from a position where the first rotating support unit supports the support column, and a housing configured to support the first rotating support unit and the second rotating support unit. The second rotating support unit and the housing or the support column and the housing are electrically insulated from each other.

This application is a continuation of International Patent Application No. PCT/JP2012/005406 filed on Aug. 28, 2012, and claims priority to Japanese Patent Application No. 2011-275074 filed on Dec. 15, 2011, the entire content of both of which is incorporated herein by reference.

### TECHNICAL FIELD

The present invention relates to a substrate holder apparatus and a vacuum processing apparatus.

### BACKGROUND ART

Conventionally, there is known an arrangement configured to supply power to the electrostatic chuck of a substrate holder by using a power supply mechanism (for example, PTL 1). A support column supports the substrate holder in PTL 1. A driving unit can rotate the support column. Since a rotating seal, a bearing, a motor, a power supply rotating mechanism, and the like, are sequentially arranged as the components of the driving unit along the rotation axis direction of the support column, the support column is long in the axis direction. Increasing the length of the support column may decrease the rotational position accuracy of the support column because of the influence of tolerances at the time of assembly and processing and increase load on the bearing because of the wobbling rotation of the support column to lead to a reduction in the service life of the bearing.

For this reason, a support column which supports a substrate holder is supported by bearings at two positions in the axial direction of the support column to improve rotational position accuracy and increase the service life of the bearings.

### CITATION LIST

### Patent Literature

PTL 1: Japanese Patent Laid-Open No. 2008-156746

### SUMMARY OF INVENTION

### Technical Problem

In a structure configured to support a support column by bearings at two positions, one bearing positions the support column, and a gap is provided between the outer circumferential portion of the support column and the inner circumferential portion of the other bearing to prevent any excessive load from being imposed on the other bearing. For this reason, a change in rotational angle caused by tolerances at the time of assembly and processing may lead to fluctuations in the contact state between the support column and the bearing placed in the gap provided with respect to the support column.

On the other hand, there is known an arrangement configured to apply bias power to a substrate upon superimposing the power on the power applied to an ESC electrode via a substrate holder. In the substrate holder designed to apply such bias power, fluctuations in the contact state with a bearing may influence the bias power applied to a substrate. More specifically, as the resistance value of the route on the feedback side of the bias power applied to a substrate changes depending on the contact state with the bearing, reflected waves may be generated by waves striking a plasma, resulting in influencing the discharge state of the plasma. Therefore, demands have arisen for a substrate holder apparatus which can further stabilize applied bias power without being influenced by a change in contact state with a bearing.

### Solution to Problem

The present invention has been made in consideration of the above problem, and has as its object to provide a technique capable of further stabilizing bias power to be applied without being influenced by a change in contact state with a bearing.

In order to achieve the above object, a substrate holder apparatus according to one aspect of the present invention is comprising:

a substrate holder configured to hold a substrate in a vacuum processing space in a chamber;

a support column coupled to the substrate holder;

a first rotating support unit configured to rotatably support the support column;

a second rotating support unit configured to rotatably support the support column at a position spaced apart from a position where the first rotating support unit supports the support column; and

a housing configured to support the first rotating support unit and the second rotating support unit,

wherein the second rotating support unit and the housing or the support column and the housing are electrically insulated from each other.

Alternatively, a substrate holder apparatus according to another aspect of the present invention is comprising:

a substrate holder configured to hold a substrate in a vacuum processing space in a chamber;

a support column coupled to the substrate holder;

a first rotating support unit configured to rotatably support the support column; and

a second rotating support unit configured to rotatably support the support column at a position spaced apart from a position where the first rotating support unit supports the support column,

wherein the support column comprises a first support column portion and a second support column portion, and

an insulating member is provided between the first support column portion and the second support column portion.

Alternatively, a vacuum processing apparatus according to still another aspect of the present invention is comprising:

a vacuum processing chamber configured to process a substrate;

a substrate holder apparatus provided inside the vacuum processing chamber; and

a processing unit configured to process a substrate configured to be held by the substrate holder apparatus.

### Advantageous Effects of Invention

According to the present invention, it is possible to further stabilize bias power to be applied without being influenced by a change in the contact state of a bearing.

It is possible to stabilize the discharge state of a plasma by stabilizing bias power.

Other features and advantages of the present invention will be apparent from the following description taken in conjunction with the accompanying drawings. Note that the same reference numerals denote the same or like components throughout the accompanying drawings.

### BRIEF DESCRIPTION OF DRAWINGS

The accompanying drawings, which are incorporated in and constitute a part of the specification, illustrate exemplary embodiments of the invention and, together with the description, serve to explain the principles of the present invention.

FIG. 1 is a view showing the arrangement of a substrate processing apparatus according to an embodiment;

FIG. 2 is a view showing an example of the arrangement of a substrate holder apparatus according to the first embodiment;

FIG. 3 is a view showing an example of the arrangement of a substrate holder apparatus according to the second embodiment;

FIG. 4 is a view showing an example of the arrangement of a substrate holder apparatus according to the third embodiment; and

FIG. 5 is a view showing an example of the arrangement of a substrate holder apparatus according to the fourth embodiment.

### DESCRIPTION OF EMBODIMENTS

Embodiments of the present invention will be described below with reference to the accompanying drawings. Note that the constituent elements described in the embodiments are merely examples. The scope of the present invention is not limited to only them.

(Arrangement of Substrate Processing Apparatus)

The arrangement of a substrate processing apparatus 100 (vacuum processing apparatus) according to an embodiment of the present invention will be described with reference to FIG. 1. The arrangement of the substrate processing apparatus 100 as an example of a sputtering apparatus will be described.

The substrate processing apparatus 100 includes a chamber 1, a stage 13, a power supply 14, a sputtering electrode 15, a sputtering power supply 17, a gas supply device 18, an exhaust device 19, an exhaust valve 20, a support column 30, a power supply unit 61, a driving unit 79, and a housing 50.

The interior (vacuum processing chamber S) of the chamber 1 is connected to the exhaust device 19 via the exhaust valve 20. The exhaust valve 20 can control the internal pressure of the chamber 1. The exhaust device 19 sets the interior of the chamber 1 to a required vacuum state suitable for a substrate process. In addition, the interior (vacuum processing chamber S) of the chamber 1 is connected to the gas supply device 18. The gas supply device 18 supplies a gas used for plasma generation into the vacuum processing chamber S of the chamber 1.

The sputtering power supply 17 functioning as an arrangement for processing a substrate supplies power to a target 16 through the sputtering electrode 15. When the sputtering power supply 17 supplies power to the target 16, the target 16 is sputtered by a sputtering discharge. A material sputtered from the target 16 is deposited on a substrate 10. A material used for the target 16 corresponds to the substance to be deposited on the substrate 10.

The exhaust device 19 evacuates the chamber 1. The gas supply device 18 then supplies a sputtering gas into the chamber 1. After pressure control by the exhaust valve 20, the sputtering power supply 17 supplies power to the sputtering electrode 15 to sputter the target 16 to form a film on the substrate 10 held on the stage 13.

The stage 13 (substrate holder) includes a substrate mounting surface on which the substrate 10 can be held in the processing space S evacuated in the chamber 1 and an electrostatic chuck for fixing the mounted substrate 10 by electrostatic adsorption. The electrostatic chuck is internally provided with an electrode 53. The electrode 53 receives required power via a power supply line 54 provided in the stage 13 and the support column 30 having a hollow structure. The power supply line 54 is covered by an insulating member 55 inside the support column 30.

The stage 13 (substrate holder) is coupled to the upper end portion of the support column. The lower end portion of the support column 30 is provided with the power supply unit 61 for supplying power to the electrode 53 of the electrostatic chuck. The power supply 14 is connected to the power supply unit 61. The power supply unit 61 supplies, via the power supply line 54, power for actuating the electrostatic chuck and bias power for controlling the properties of a film or a sputtering coverage.

In order to improve the uniformity of a film formation distribution on a substrate surface, the driving unit 79 rotates the substrate 10 held on the stage 13 through the support column 30.

The driving unit 79 includes a movable element portion 77 placed on the outer circumferential portion of the support column 30 and a stator portion 58 fixed to the inner circumferential surface of the housing 50. The driving unit 79 functions as a motor for rotating the support column 30 owing to the interaction between the movable element portion 77 and the stator portion 58 placed around the movable element portion 77. Assume that in this case, the housing 50 is connected to the chamber 1 and grounded through the chamber 1.

A bearing 57 (main bearing) and a bearing 59 (sub-bearing) support the rotation of the support column 30 by the driving unit 79.

The outer circumferential portions of the bearings 57 and 59 are fixed to the inner circumferential surface of the housing 50. A vacuum rotating seal 56 is provided between the support column 30 and the housing 50 to maintain a vacuum atmosphere in the chamber 1.

Of the components of the substrate processing apparatus 100 (vacuum processing apparatus), the stage 13, the support column 30, the bearing 57, the bearing 59, and the housing 50 constitute a substrate holder apparatus capable of holding a substrate. The arrangement of the substrate holder apparatus according to an embodiment of the present invention will be described in detail below.

### First Embodiment

FIG. 2 is a view showing an example of the arrangement of a substrate holder apparatus 200 according to the first embodiment of the present invention. The same reference numerals as in FIG. 1 denote the same components in FIG. 2, and a description of them will be omitted.

A main bearing 157 (first rotating support member) positions a support column 130 and rotatably supports the support column 130. A sub-bearing 159 (second rotating support member) rotatably supports the support column 130. A housing 150 holds the outer circumferential portions of the main bearing 157 and sub-bearing 159. Although the main bearing 157 is constituted by a plurality of bearings, the main bearing 157 may be formed from one bearing.

A slight gap is provided between the inner circumferential portion of the sub-bearing 159 and the outer circumferential portion of the support column 130. This gap can prevent a deterioration in the rotational position accuracy of the support column caused by tolerances at the time of assembly of the substrate holder apparatus 200 and processing on the support column 130 and reduce the load on the sub-bearing 159 which is imposed by the wobbling rotation of the support column.

A stepped portion 135 is formed on the outer circumferential portion of the support column 130 which faces the inner circumferential portion of the sub-bearing 159. An electric insulating member 160 is placed in the stepped portion 135. The electric insulating member 160 has an annular shape and is fitted in the stepped portion 135 of the support column 130. The electric insulating member 160 fitted in the stepped portion 135 can rotate together with the support column 130, and is configured such that the outer circumferential portion of the electric insulating member 160 comes into contact with the inner circumferential portion of the sub-bearing 159. The sub-bearing 159 which comes into contact with the electric insulating member 160 is insulated from the support column 130. Placing the electric insulating member 160 between the support column 130 and the sub-bearing 159 electrically insulates the support column 130 from the housing 150. Even if the contact state between the sub-bearing 159 and the support column 130 changes as the support column 130 rotates, the electric insulating member 160 shuts off a potential from the support column 130 side. Since the potential from the support column 130 side is not conducted to the housing 150 through the sub-bearing 159 in contact with the electric insulating member 160, the conductive state of the substrate holder apparatus 200 does not change in a substrate processing apparatus 100. According to this embodiment, it is possible to further stabilize bias power to be applied without being influenced by a change in the contact state of the sub-bearing 159. Stabilizing the bias power can stabilize the discharge state of a plasma.

Note that FIG. 2 shows an example of the arrangement in which the main bearing 157 is placed on the stage 13 side (upper side), and the sub-bearing 159 is placed on the lower side relative to the main bearing 157. The scope of the present invention is not limited to this example. The present invention can also be applied to an arrangement in which the sub-bearing 159 is placed on the stage 13 side (upper side), and the main bearing 157 is placed on the lower side relative to the sub-bearing 159. That is, the present invention can be applied to an arrangement in which two bearings (the main bearing 157 and the sub-bearing 159) are arranged apart from each other along the rotation axis direction of the support column 130.

### Second Embodiment

FIG. 3 is a view showing an example of the arrangement of a substrate holder apparatus 300 according to the second embodiment of the present invention. A main bearing 257 (first rotating support portion) positions a support column 230 and rotatably supports the support column 230. A sub-bearing 259 (second rotating support portion) rotatably supports the support column 230. A housing 250 holds the outer circumferential portion of the main bearing 257. The housing 250 facing the outer circumferential portion of the sub-bearing 259 is provided with an electric insulating member 260. The sub-bearing 259 is fixed to the housing 250 while the outer circumferential portion of the sub-bearing 259 is in contact with the electric insulating member 260.

A slight gap is provided between the inner circumferential portion of the sub-bearing 259 and the outer circumferential portion of the support column 230. This gap can prevent a deterioration in the rotational position accuracy of the support column caused by tolerances at the time of assembly of the substrate holder apparatus 300 and processing on the support column 230 and reduce the load on the sub-bearing 259 which is imposed by the wobbling rotation of the support column.

The sub-bearing 259 which comes into contact with the electric insulating member 260 is insulated from the housing 250. Placing the electric insulating member 260 between the housing 250 and the sub-bearing 259 electrically insulates the support column 230 from the housing 250. Even if the contact state with the sub-bearing 259 changes as the support column 230 rotates, the electric insulating member 260 shuts off a potential through the support column 230 and the sub-bearing 259. Since the potential from the support column 230 side is not conducted to the housing 250, the conductive state of the substrate holder apparatus 300 does not change. According to this embodiment, it is possible to further stabilize bias power to be applied without being influenced by a change in the contact state of the sub-bearing 259. Stabilizing bias power can stabilize the discharge state of a plasma.

Note that FIG. 3 shows an example of the arrangement in which the main bearing 257 is placed on the stage 13 side (upper side), and the sub-bearing 259 is placed on the lower side relative to the main bearing 257. The scope of the present invention is not limited to this example. The present invention can also be applied to an arrangement in which the sub-bearing 259 is placed on the stage 13 side (upper side), and the main bearing 257 is placed on the lower side relative to the sub-bearing 259. That is, the present invention can be applied to an arrangement in which two bearings (the main bearing 257 and the sub-bearing 259) are arranged apart from each other along the rotation axis direction of the support column 230.

### Third Embodiment

FIG. 4 is a view showing an example of the arrangement of a substrate holder apparatus 400 according to the fourth embodiment of the present invention. A support column 330 includes first and second support column portions 331 and 332 obtained by dividing a support column having a hollow structure into two portions and an electric insulating member 360 provided between the first support column portion 331 and the second support column portion 332. The electric insulating member 360 having a hollow structure is inserted between the lower surface of the first support column portion 331 and the upper surface of the second support column portion 332, which are obtained by dividing the support column having the hollow structure into two portions, to form the integral support column 330 having the hollow structure.

A main bearing 357 (first rotating support portion) is placed on the first support column portion 331 side. The main bearing 357 positions the first support column portion 331 (support column 330) and rotatably supports the support column 330. A sub-bearing 359 (second rotating support portion) is placed on the second support column portion 332 side, and rotatably supports the second support column portion 332 (the support column 330).

A housing 350 holds the outer circumferential portions of the main bearing 357 and sub-bearing 359. A slight gap is provided between the inner circumferential portion of the sub-bearing 359 and the outer circumferential portion of the second support column portion 332 (support column 330). This gap can prevent a deterioration in the rotational position accuracy of the support column 330 caused by tolerances at the time of assembly of the substrate holder apparatus 400 and processing on the support column 330 and reduce the load on the sub-bearing 359 which is imposed by the wobbling rotation of the support column 330.

Placing the electric insulating member 360 between the first support column portion 331 and the second support column portion 332 electrically insulates the first support column portion 331 side above the electric insulating member 360 from the second support column portion 332 side below the electric insulating member 360. Even if the contact state with the sub-bearing 359 changes as the support column 330 rotates, the electric insulating member 360 shuts off a potential from the first support column portion 331 side including a stage 13 (substrate holder). Since the potential from the first support column portion 331 side including the stage 13 (substrate holder) is not conducted to the housing 350 through the second support column portion 332 and the sub-bearing 359, the conductive state of the substrate holder apparatus 400 does not change. According to this embodiment, it is possible to further stabilize bias power to be applied without being influenced by a change in the contact state of the sub-bearing 359. Stabilizing bias power can stabilize the discharge state of a plasma.

Note that FIG. 4 shows an example of the arrangement in which the main bearing 357 is placed on the stage 13 side (upper side), and the sub-bearing 359 is placed on the lower side relative to the main bearing 357.

The spirit of the present invention is not limited to this example. The present invention can also be applied to an arrangement in which the sub-bearing 359 is placed on the stage 13 side (upper side), and the main bearing 357 is placed on the lower side relative to the sub-bearing 359. In this case, the support column 330 may be divided in the interval between the stage 13 and the position at which the sub-bearing 359 supports the support column 330, and the electric insulating member 360 may be inserted at the position where the support column 330 is divided. With this arrangement, the present invention can be applied to an arrangement in which the two bearings (the main bearing 357 and the sub-bearing 359) are arranged apart from each other along the rotation axis direction of the support column 330.

### Fourth Embodiment

FIG. 5 is a view showing an example of the arrangement of a substrate holder apparatus 500 according to the fourth embodiment of the present invention. The same reference numerals as in FIG. 1 denote the same components in FIG. 5, and a description of them will be omitted.

A main bearing 457 (first rotating support member) positions a support column 430 and rotatably supports the support column 430. A sub-bearing 459 (second rotating support member) rotatably supports the support column 430. A housing 450 holds the outer circumferential portions of the main bearing 457 and sub-bearing 459.

A slight gap is provided between the inner circumferential portion of the sub-bearing 459 and the outer circumferential portion of the support column 430. This gap can prevent a deterioration in the rotational position accuracy of the support column 430 caused by tolerances at the time of assembly of the substrate holder apparatus 400 and processing on the support column 430 and reduce the load on the sub-bearing 459 which is imposed by the wobbling rotation of the support column 430.

The sub-bearing 459 is formed from an insulating member. The constituent elements formed from insulating members include the outer circumferential portion held by the housing 450, the inner circumferential portion which supports the support column 430, balls (rotating conductors) which make the inner circumferential portion rotatable relative to the outer circumferential portion, and a holding portion for the rotating conductors. The scope of the present invention is not limited to that all the constituent elements of the sub-bearing 459 are formed from insulating members as long as it is possible to shut off potential from the support column 430 side by using an insulating member as a constituent element of the sub-bearing 459. Even when the sub-bearing 459 is formed as a modification such that one of the inner circumferential portion and the outer circumferential portion is formed from an insulating member, the same effects as those described above can be obtained.

Using the sub-bearing 459 formed from an insulating member electrically insulates the support column 430 from the housing 450. Even if the contact state between the sub-bearing 459 and the support column 430 changes as the support column 430 rotates, the sub-bearing 459 shuts off a potential from the support column 430 side. Since the potential from the support column 430 side is not conducted to the housing 450 through the sub-bearing 459, the conductive state of the substrate holder apparatus 500 does not change. According to this embodiment, it is possible to further stabilize bias power to be applied without being influenced by a change in the contact state of the sub-bearing 459. Stabilizing bias power can stabilize the discharge state of a plasma.

Note that FIG. 5 shows an example of the arrangement in which the main bearing 457 is placed on the stage 13 side (upper side), and the sub-bearing 459 is placed on the lower side relative to the main bearing 457. The scope of the present invention is not limited to this example. The present invention can also be applied to an arrangement in which the sub-bearing 459 is placed on the stage 13 side (upper side), and the main bearing 457 is placed on the lower side relative to the sub-bearing 459. That is, the present invention can be applied to an arrangement in which two bearings (the main bearing 457 and the sub-bearing 459) are arranged apart from each other along the rotation axis direction of the support column 430.

The present invention is not limited to the above embodiments and various changes and modifications can be made within the spirit and scope of the present invention. Therefore, to apprise the public of the scope of the present invention, the following claims are made.

1. A substrate holder apparatus comprising:
a substrate holder configured to hold a substrate in a vacuum processing space in a chamber;
a support column coupled to said substrate holder;
a first rotating support unit configured to rotatably support said support column;
a second rotating support unit configured to rotatably support said support column at a position spaced apart from a position where said first rotating support unit supports said support column; and
a housing configured to support said first rotating support unit and said second rotating support unit,
wherein said second rotating support unit and said housing or said support column and said housing are electrically insulated from each other.

2. The substrate holder apparatus according to claim 1, wherein an insulating member is provided between said second rotating support unit and an outer circumferential portion of said support column supported by said second rotating support unit.

3. The substrate holder apparatus according to claim 1, wherein an insulating member is provided between said housing and an outer circumferential portion of said second rotating support unit supported by said housing.

4. The substrate holder apparatus according to claim 1, wherein said second rotating support unit comprises an insulating member.

5. A substrate holder apparatus comprising:
a substrate holder configured to hold a substrate in a vacuum processing space in a chamber;
a support column coupled to said substrate holder;
a first rotating support unit configured to rotatably support said support column; and
a second rotating support unit configured to rotatably support said support column at a position spaced apart from a position where said first rotating support unit supports said support column,
wherein said support column comprises a first support column portion and a second support column portion, and
an insulating member is provided between said first support column portion and said second support column portion.

6. The substrate holder apparatus according to claim 1, further comprising a power supply unit configured to supply power from a power supply to an electrode of said substrate holder via a power supply line provided in said support column.

7. A vacuum processing apparatus comprising:
a vacuum processing chamber configured to process a substrate;
a substrate holder apparatus defined in claim 1 which is provided inside said vacuum processing chamber; and
a processing unit configured to process a substrate configured to be held by said substrate holder apparatus.
